(19) United States
(12) Patent Application Publication
(10) Pub. No.: US 2010/0301820 A1
(43) Pub. Date: Dec. 2, 2010

(54) HIGH WITHSTAND VOLTAGE SEMICONDUCTOR DEVICE AND CURRENT CONTROL DEVICE USING THE SAME

(75) Inventor: Saichirou KANEKO, Kyoto (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/716,438

(22) Filed: Mar. 3, 2010

(30) Foreign Application Priority Data
May 28, 2009 (JP) 2009-129547

(51) Int. Cl. G05F 1/00; H01L 29/739

(52) U.S. Cl. 323/282; 257/139; 257/E29.197

(57) ABSTRACT

To provide a high withstand voltage semiconductor device capable of accurately detecting a switch between a MOS operation and an IGBT operation, and thereby achieving a low-loss drive, and a current control device using the same. The semiconductor device includes: an N-type resurf region 5 formed on a P⁻-type substrate 1; a P-type base region 10; an N⁺-type emitter/source region 14; a gate insulation film 7; an N⁺-type drain region 32 and a P-type collector region 31 formed in the resurf region 5; a gate electrode 90; a collector/drain electrode 110; a back gate electrode 62; and an emitter/source electrode 61, wherein the P-type collector region 31 and the N⁺-type drain region 32 are arranged such that their parts are alternately in contact with each other.

### BACKGROUND OF THE INVENTION

(1) Field of the Invention

The present invention relates to high withstand voltage semiconductor devices and current control devices using the same, and in particular to a high withstand voltage semiconductor device which repeatedly opens and closes a main current to be used especially for a switching power source device, and to a current control device using the same.

(2) Description of the Related Art

Recent years have seen strong demands for switching power source devices which achieve low power consumption during standby. Such switching power source devices include, for example, a rectification smoothing circuit, a transformer, and a body circuit including a semiconductor switching element.

In the device configured as mentioned above, power losses occur mainly in the semiconductor switching element. Accordingly, a MOSFET (Metal Oxide Semiconductor Field Effect Transistor) is used as this semiconductor switching element because the MOSFET produces less switching losses than a bipolar transistor does. However, the MOSFET produces a significant conduction resistance which cannot be ignored. Accordingly, a high current that flows in the MOSFET increases losses in the whole switching power source device.

To prevent this, considering both the switching losses and conduction losses, a high withstand voltage semiconductor device has been proposed (Patent Reference: Japanese Unexamined Patent Application Publication No. 2007-115871) which functions as a MOSFET advantageous in the case of high frequency and low current while a light load is placed, for example, in a wait mode whereas it functions as an IGBT (Insulated Gate Bipolar Transistor) having a small conduction resistance and thus advantageous in the case of low frequency and high current while a heavy load is placed.

FIG. 9 is a diagram showing an exemplary high withstand voltage semiconductor device having three electrodes disclosed in Patent Reference 1.

This high withstand voltage semiconductor device 500 includes three electrodes that are an emitter/source electrode 521, a gate electrode 522, and a collector/drain electrode 520.

An N-type resurf region 505 is formed on the P⁻-type substrate 501. In the P⁻-type substrate 501, a P-type base region 502 is also formed adjacent to the resurf region 505. In the P-type base region 502, an N⁺-type emitter/source region 504 and P⁺-type base contact region 503 are formed apart from the resurf region 505. Further, a gate insulation film 507 is formed to cover the P-type base region 502 at a part between the N⁺-type emitter/source region 504 and the resurf region 505. In the resurf region 505, an N⁺-type drain region 562 is formed apart from the P-type base region 502. Further in the resurf region 505, a P-type collector region 561 is formed apart from the P-type base region 502. The P-type collector region 561 and the N⁺-type drain region 562 are each configured with separate parts, and arranged such that the respective parts of the P-type collector region 561 and the respective parts of the N⁺-type drain region 562 are alternately in contact with each other in a direction vertical to the direction from the P-type collector region 561 to the N⁺-type emitter/source region 504.

Further, a gate electrode 522 is formed on the gate insulation film 507, and on the P⁻-type substrate 501, a collector/drain electrode 520 is disposed in electrical contact with both the P-type collector region 561 and the N⁺-type drain region 562. In addition, on the P⁻-type substrate 501, an emitter/source electrode 521 is formed connected to both the P⁺-type base contact region 503 and the N⁺-type emitter/source region 504. This emitter/source electrode 521 is connected to a metal layer 523 deposited on the back surface of the P⁻-type substrate 501. In addition, on the resurf region 505, an inter-layer film 512 is formed through a field insulation film 509.

FIG. 10 is a diagram showing an equivalent circuit of the high withstand voltage semiconductor device disclosed in Patent Reference 1. As shown in FIG. 10, the high withstand voltage semiconductor device 500 as the equivalent circuit includes three terminals P1, P2, and P3 which are electrically connected to the collector/drain electrode 520, the gate electrode 522, and the emitter/source electrode 521, respectively. The potential of the P⁻-type substrate 501 generally called as a back gate and the potential of the P-type base region 502 are connected to Terminal P3 as shown in the back gate line 524 in FIG. 10.

This high withstand voltage semiconductor device 500 applies a positive bias to between the collector/drain electrode 520 and the emitter/source electrode 521, and applies a positive voltage to the gate electrode 522. This causes a current to start flowing from the N⁺-type drain region 562 to the emitter/source electrode 521 (MOSFET operation). When the current increases to a certain level and the potential of the resurf region 505 around the P-type collector region 561 decreases to a voltage lower than the voltage of the P-type collector region 561 by approximately 0.6 V, holes are injected from the P-type collector region 561 to transit to an IGBT operation.

FIG. 11 is a graph showing correlations between collector/drain voltages and collector/drain currents of the high withstand voltage semiconductor device. Here, it is assumed that the collector/drain voltage for switching a MOSFET operation to an IGBT operation is Vch, and that the collector/drain current at the time of the switching is Ich. FIG. 11 shows an example where Vch is approximately 2 V, and Ich is approximately 1 A. In this way, the high withstand voltage semiconductor device 500 can cause a MOSFET operation when the collector/drain current flowing in the element is comparatively small, and cause an IGBT operation when the collector/drain current becomes high. In other words, the high withstand voltage semiconductor device 500 can selectively use the two types of MOSFET and IGBT operations within a single element.

FIG. 12 is a diagram showing a general circuit configuration of a current control device using the high withstand voltage semiconductor device disclosed in Patent Reference 1. In the diagram, Terminal P3 is connected (grounded) to a common electrode 560 through a sense resistor 558 which is a resistor used to detect a current. In addition, a reference voltage generator circuit 557 is connected to the common electrode 560. Further, a comparator circuit 556 is provided to compare (i) a voltage in the sense resistor 558 which is generated when a current 555 flows into the sense resistor 558 with (ii) a reference voltage generated by the reference voltage generator circuit 557. The comparator circuit 556 is connected to both the reference voltage generator circuit 557 and Terminal P3.

A method for detecting and controlling a current flowing in the high withstand voltage semiconductor device 500 having the circuit configuration shown in FIG. 12 includes applying a positive bias to Terminals P1 and P3 and applying a positive voltage to Terminal P2 to cause the current 555 to flow from Terminal P1 to Terminal P3. As the current 555 increases, the voltage generated in the sense resistor 558 increases more significantly. When the voltage becomes equal to the reference voltage generated by the reference voltage generator circuit 557, a signal is propagated from the comparator circuit 556 to the gate voltage application circuit 554. This turns off Terminal P2 having a positive bias, which makes the voltage equal to the voltage of the common electrode 560, resulting in a cut-off of the current 555.

However, the high withstand voltage semiconductor device having three electrodes and the current control device using the same disclosed in Patent Reference 1 entails a problem of not being able to accurately detect the collector/drain voltage Vch for switching from a MOS operation to an IGBT operation and a corresponding collector/drain current Ich. For example, since Ich is 1 A, the high withstand voltage semiconductor device 500 shown in FIG. 10 can detect, using a sense resistor 558 having a resistance of 0.1Ω, the collector/drain current Ich corresponding to the potential 0.1 V of Terminal P3 as indicating a switch from a MOS operation to an IGBT operation. However, it is known that Ich has a temperature dependency and thus that, for example, 1 A at room temperature decreases to 0.6 A at 100 degrees Celsius. According to the conventional method, the collector/drain current 1ch is erroneously detected as 1 A even when the temperature is 100 degrees Celsius, and therefore an accurate Ich according to temperature change cannot be detected. In addition, the high withstand voltage semiconductor device 500 allows variation in Ich values, and thus an Ich that should be 1 A intrinsically may be decreased to, for example, 0.8 A due to such variation. However, according to the conventional method, 1 A is erroneously detected as the collector/drain current Ich. Therefore, the conventional method entails a problem that it is impossible to accurately detect Vch and Ich with which the high withstand voltage semiconductor device 500 switches from a MOS operation to an IGBT operation.

Next, a description is given of a problem produced due to the inability of detecting such switch from the MOS operation to the IGBT operation. As clear from FIG. 11, in the MOS operation region in which Vch is smaller than 2 V, the current drive capability is maintained as long as the voltage of Terminal P2, that is, the gate voltage Vg is not less than 6 V. In contrast, in the IGBT operation region in which Vch is greater than 2 V, the current drive capability is greatly different. The use of 12 V as Vg reduces losses caused by a turned-on resistor more significantly than in the case of using 6 V as Vg. On the other hand, the use of 6 V as Vg makes it possible to reduce drive losses more significantly than in the case of using 12 V as Vg.

Accordingly, in order to reduce losses throughout the period from the MOS operation to the IGBT operation to an optimum level, it is necessary to reduce drive losses using 6 V as the gate voltage during the MOS operation and reduce losses by the turned-on resistor using 12 V as the gate voltage during the IGBT operation. At this time, in order to reduce losses to an optimum level, it is a must to accurately detect the switch from the MOS operation to the IGBT operation and switch the gate voltage properly.

### SUMMARY OF THE INVENTION

In view of the above-described problems, the present invention has an object to provide a high withstand voltage semiconductor device capable of accurately detecting a switch from a MOS operation to an IGBT operation, thereby achieving a low-loss drive, and provide a current control device including the high withstand voltage semiconductor device.

In order to achieve the above-described object, the high withstand voltage semiconductor device according to a first aspect of the present invention includes: a second conductive-type resurf region formed on a surface part of a first conductive-type semiconductor substrate; a first conductive-type base region formed adjacent to the resurf region in the semiconductor substrate; a second conductive-type emitter/source region formed in the base region and apart from the resurf region; a gate insulation film formed on the semiconductor substrate to cover the base region at a part between the emitter/source region and the resurf region; a second conductive-type drain region formed in the resurf region and apart from the base region; a first conductive-type collector region formed in the resurf region and apart from the base region; a gate electrode formed on the gate insulation film; a collector/drain electrode formed on the semiconductor substrate and electrically connected to both the collector region and the drain region; a back gate electrode formed on the semiconductor substrate and electrically connected to the base region; and an emitter/source electrode formed on the semiconductor substrate and electrically connected to the emitter/source region, wherein the collector region and the drain region are each configured with separate parts, and arranged such that the respective parts of the collector region and the respective parts of the drain region are alternately in contact with each other in a direction perpendicular to a direction from the collector region to the emitter/source region.

The conventional three-terminal element including a gate electrode, a collector/drain electrode, and an emitter/source electrode has a problem of being not able to separately detect an electron current and a hole current during a turned-on state.

The four-terminal element configured to additionally have a back gate electrode makes it possible to separately detect an electron current and a hole current during a turned-on state. This allows an accurate detection of a switch from a MOS operation to an IGBT operation, thereby enabling a low-loss drive.

In addition, in order to achieve the above-described object, the current control device according to a second aspect of the present invention may include: the high withstand voltage semiconductor device according to the first aspect; and a current control unit configured to control a collector/drain current according to a result of detection of a value of at least one of (i) a first current flowing into the emitter/source electrode in the collector/drain current of the high withstand voltage semiconductor device and (ii) a second current flowing into the back gate electrode in the collector/drain current.

With this, it is possible to detect either the electron current or the hole current that is generated from a corresponding one of the emitter/source electrode and the back gate electrode of the high withstand voltage semiconductor device during a turned-on state. Therefore, it is possible to achieve a current control device capable of accurately detecting a switch from a MOS operation to an IGBT operation and performing a low-loss drive.

In addition, the back gate electrode may be connected to a common electrode having a constant potential at least in the current control unit, and the current control unit may include: a first resistor element which is inserted between the emitter/source electrode and the common electrode, and is configured to detect the first current flowing into the common electrode; a first reference voltage generator circuit which generates a first reference voltage that is a potential with respect to the potential of the common electrode; a first comparator circuit which has a first input terminal connected to the emitter/source electrode and has a second input terminal connected to the first reference voltage generator circuit, and compares (i) a first voltage generated between both terminals of the first resistor element with (ii) the first reference voltage; and a current control circuit which controls the collector/drain current according to a result of the comparison made by the first comparator circuit.

According to this implementation, since the first resistor element for detecting a current is connected to the emitter/source electrode, and the back gate electrode is connected to the common electrode, the emitter/source electrode has a potential greater than the potential of the back gate electrode during a turned-on state in which a current is flowing. As a result, this implementation has an advantageous feature of having a great resistance against a so-called latch-up phenomenon compared to the conventional implementations. The latch-up phenomenon is a phenomenon in which an undesirable current flows from a base region to an emitter/source region when the base region has a potential greater than the potential of the emitter/source region by approximately 0.6 V.

In addition, the current that flows into the first resistor element is only the electron current that flows into the emitter/source electrode. On the other hand, in the case of the conventional current control device shown in FIG. 12, the current 555 that flows into the sense resistor 558 is a sum of the electron current and the hole current. Compared to the conventional current control device, this implementation has an advantageous feature of being able to reduce the current that flows into the resistor for detecting a current when the same amount of collector/drain current is applied thereto, and thereby reducing losses generated in the resistor.

In addition, the emitter/source electrode may be connected to a common electrode having a constant potential at least in the current control unit, and the current control unit may include: a second resistor element which is inserted between the back gate electrode and the common electrode, and is configured to detect the second current flowing into the common electrode; a second reference voltage generator circuit which generates a second reference voltage that is a potential with respect to the potential of the common electrode; a second comparator circuit which has a first input terminal connected to the back gate electrode and a second input terminal connected to the second reference voltage generator circuit, and compares (i) a second voltage generated between the both terminals of the second resistor element with (ii) the second reference voltage; and a current control circuit which controls the collector/drain current according to a result of the comparison made by the second comparator circuit.

According to this implementation, since the second resistor element for detecting a current is connected to the back gate electrode, and the emitter/source electrode is connected to the common electrode, the hole current that starts flowing when the high withstand voltage semiconductor device switches from a MOS operation to an IGBT operation is connected to the back gate electrode, and is detected by the second resistor element. Accordingly, the present invention enables an accurate detection of a switch from a MOS operation to an IGBT operation although the conventional current control device shown in FIG. 12 cannot perform such detection.

In addition, the current that flows into the second resistor element is only the hole current that flows into the back gate electrode. On the other hand, in the case of the conventional current control device shown in FIG. 12, the current 555 that flows into the sense resistor 558 is a sum of the electron current and the hole current. Compared to the conventional current control device, this implementation has an advantageous feature of being able to reduce the current that flows into the resistor for detecting a current when the same amount of collector/drain current is applied thereto, and thereby reducing losses generated in the resistor.

In addition, the current control unit may further include a resistor element for preventing a latch-up which is inserted between the emitter/source electrode and the common electrode and is configured to prevent a latch-up.

According to this implementation, since a resistor for preventing a latch-up is connected to the emitter/source electrode, it is possible to increase resistance against the so-called latch-up that is a phenomenon in which an undesirable current flows from the base region to the emitter/source region.

In addition, the current control unit may further include: a third resistor element which is inserted between the emitter/source electrode and the common electrode, and is configured to detect the first current flowing into the common electrode; a third reference voltage generator circuit which generates a third reference voltage that is a potential with respect to the potential of the common electrode; and a third comparator circuit which has a first input terminal connected to the emitter/source electrode and a second input terminal connected to the third reference voltage generator circuit, and compares (i) a third voltage generated between the both terminals of the third resistor element with (ii) the third reference voltage, wherein the current control circuit may control the collector/drain current according to a result of the comparison made by the first and third comparator circuits.

According to this implementation, a resistor for detecting a current and a comparator circuit are provided for each of the emitter/source electrode and the back gate electrode. Therefore, this implementation has an advantageous feature of being able to detect even an electron current during a MOS operation, unlike a current control device in which the second resistor element is connected only to the back gate electrode. In addition, since the third resistor element for detecting a current is connected to the emitter/source electrode, it is possible to increase resistance against the so-called latch-up that is a phenomenon in which an undesirable current flows from the base region to the emitter/source region, unlike the case where the resistor is not connected.

In addition, the current control circuit may include a gate voltage selection circuit which: increases a gate voltage value of the high withstand voltage semiconductor device according to a signal received from the second comparator circuit when the second voltage reaches or exceeds the second reference voltage; and decreases a gate voltage value of the high withstand voltage semiconductor device according to a signal received from the second comparator circuit when the second voltage reaches or falls below the second reference voltage.

According to this implementation with a gate voltage selection circuit which receives a signal from a comparator circuit, it is possible to detect a switch from a MOS operation to an IGBT operation of the high withstand voltage device, and for example, can cause the gate voltage selection circuit to switch the gate voltage of 6 V during an MOS operation to 12 V at the time of transition into an IGBT operation. Thereby, this implementation has an advantageous feature of being able to reduce gate drive losses during the MOS operation, and reduce losses in the turned-on resistor during the IGBT operation.

According to the high withstand voltage semiconductor device and the current control device using the same in the present invention, it is possible to perform an accurate detection of a switch from an MOS operation to an IGBT operation, thereby enabling a low-loss drive.

### FURTHER INFORMATION ABOUT TECHNICAL BACKGROUND TO THIS APPLICATION

The disclosure of Japanese Patent Application No. 2009-129547 filed on May 28, 2009 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a perspective view of a high withstand voltage semiconductor device according to an embodiment of the present invention;

FIG. 2 is an equivalent circuit of a high withstand voltage semiconductor device according to an embodiment of the present invention;

FIG. 3 is a diagram showing a circuit configuration of a current control device according to Embodiment 1 of the present invention;

FIG. 4 is a diagram showing a circuit configuration of a current control device according to Embodiment 2 of the present invention;

FIG. 5 is a diagram showing a circuit configuration of a current control device according to Embodiment 3 of the present invention;

FIG. 6 is a diagram showing a circuit configuration of a current control device according to Embodiment 4 of the present invention;

FIG. 7 is a diagram showing a circuit configuration of a current control device according to Embodiment 5 of the present invention;

FIG. 8 is a diagram showing a circuit configuration of a current control device according to Embodiment 6 of the present invention;

FIG. 9 is a diagram showing an exemplary high withstand voltage semiconductor device having three electrodes disclosed in Patent Reference 1;

FIG. 10 is a diagram showing an equivalent circuit of the high withstand voltage semiconductor device disclosed in Patent Reference 1;

FIG. 11 is a graph showing correlations between collector/drain voltages and collector/drain currents of the high withstand voltage semiconductor device; and

FIG. 12 is a diagram showing a general circuit configuration of a current control device using the high withstand voltage semiconductor device disclosed in Patent Reference 1.

### DESCRIPTION OF THE PREFERRED EMBODIMENTS

### Embodiment 1

A high withstand voltage semiconductor device in this embodiment includes: an N-type resurf region formed on the surface part of a P-type semiconductor substrate; a P-type base region formed adjacent to the resurf region; an N-type emitter/source region formed in said base region and apart from said resurf region; a gate insulation film formed to cover the base region at a part between the emitter/source region and the resurf region; an N-type drain region and an N-type collector region formed in said resurf region and apart from said base region; a gate electrode formed on said gate insulation film; a collector/drain electrode electrically connected to both the collector region and the drain region; a back gate electrode electrically connected to the base region; and an emitter/source electrode electrically connected to the emitter/source region, wherein the collector region and the drain region are each configured with separate parts, and arranged such that the respective parts of the collector region and the respective parts of the drain region are alternately in contact with each other in the direction vertical to the direction from the collector region to the emitter/source region.

Configuring a high withstand voltage semiconductor device as a four-terminal element additionally including a back gate electrode enables the semiconductor device to separately detect an electron current and a hole current during a turned-on state. This allows the semiconductor device to accurately detect a switch from a MOS operation to an IGBT operation, and perform a low-loss drive.

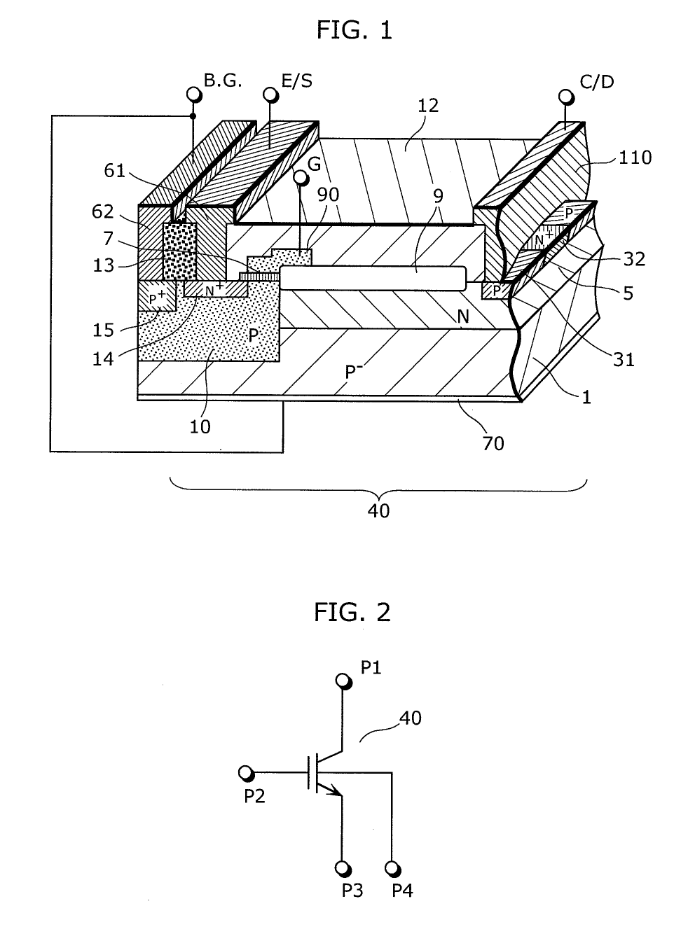

FIG. 1 is a perspective view of the high withstand voltage semiconductor device according to this embodiment of the present invention. A high pressure resistant semiconductor device 40 shown in the diagram includes four electrodes which are an emitter/source electrode 61, a back gate electrode 62, a gate electrode 90, and a collector/drain electrode 110.

An N-type resurf region 5 is formed on the surface part of a P⁻-type substrate 1. A P-type base region 10 is formed adjacent to the resurf region 5 in the P⁻-type substrate 1. In the P-type base region 10, an N⁺-type emitter/source region 14 and a P⁺-type base contact region 15 are formed apart from the resurf region 5.

Further, a gate insulation film 7 is formed to cover the P-type base region 10 at a part between the N⁺-type emitter/source region 14 and the resurf region 5.

In the resurf region 5, an N⁺-type drain region 32 is formed apart from the P-type base region 10, and P-type collector region 31 is also formed apart from the P-type base region 10. The P-type collector region 31 and the N⁺-type drain region 32 are each configured with separate parts, and are arranged such that the respective parts of the P-type collector region 31 and the respective parts of the N⁺-type drain region 32 are alternately in contact with each other in the direction vertical to the direction from the P-type collector region 31 to the N⁺-type emitter/source region 14.

Further, a gate electrode 90 is formed on the gate insulation film 7.

In addition, on the P⁻-type substrate 1, a collector/drain electrode 110 is disposed in electrical contact with both the P-type collector region 31 and an N⁺-type drain region 32.

In addition, on the P⁻-type substrate 1, an emitter/source electrode 61 is formed in contact with the N⁺-type emitter/source region 14.

In addition, on the P⁻-typesubstrate 1, a back gate electrode 62 is formed in contact with the P⁺-type base contact region 15. This back gate electrode 62 is either electrically connected with a metal layer 70 deposited on the back surface of the P⁻-type substrate 1, or connected through a later-described sense resistor.

In addition, on the resurf region 5, an inter-layer film 12 is formed through a field insulation film 9.

FIG. 2 is an equivalent circuit of a high pressure resistant semiconductor device according to this embodiment of the present invention. As an equivalent circuit, the high withstand voltage semiconductor device 40 includes four terminals P1, P2, P3, and P4 electrically connected to the collector/drain electrode 110, the gate electrode 90, the emitter/source electrode 61, and the back gate electrode 62, respectively.

This high withstand voltage semiconductor device 40 applies a positive bias to between the collector/drain electrode 110 and the emitter/source electrode 61 to apply the positive voltage to the gate electrode 90, which causes a current to start flowing from the N⁺-type drain region 32 to the emitter/source electrode 61 (MOSFET operation).

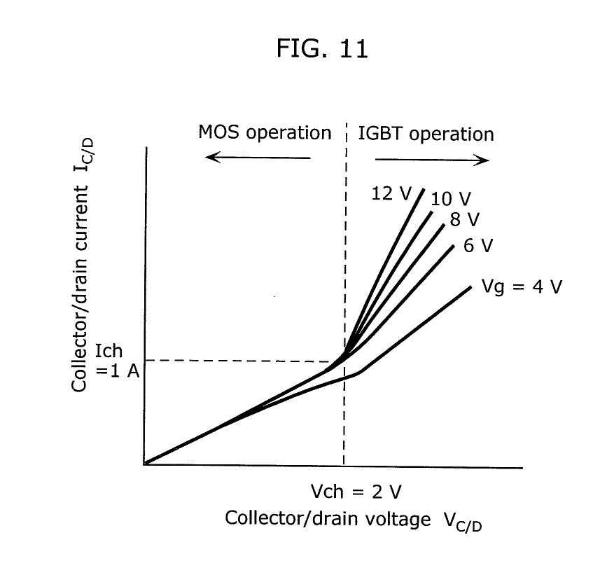

When the current increases to a certain level (1 A in the example of FIG. 11) and then the potential of the resurf region 5 around the P-type collector region 31 decreases to a voltage lower than the voltage of the P-type collector region 31 by approximately 0.6 V, holes are injected from the P-type collector region 31 to transit to an IGBT operation. When the transition to the IGBT operation is completed, a hole current starts flowing into the back gate electrode 62. The correlation between the collector/drain voltage and the collector/drain current at this time is as shown in FIG. 11. Assuming that the collector/drain voltage for switching from a MOSFET operation to an IGBT operation is Vch, and that the collector/drain current at that time is Ich, Vch and Ich are approximately 2 V and 1 A, respectively. In this way, the high withstand voltage semiconductor device 40 can cause a MOSFET operation when the collector/drain current flowing in the element is comparatively small, and causes an IGBT operation when the collector/drain current increases, that is, the semiconductor device can selectively use the two types of the MOSFET operation and the IGBT operation in a single element.

Next, a description is given of a current control device using a high withstand voltage semiconductor device 40 according to this embodiment of the present invention.

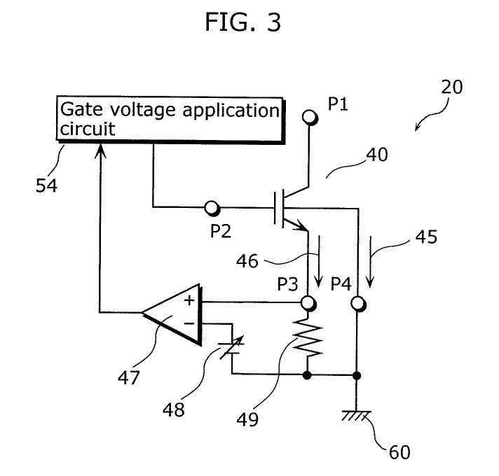

FIG. 3 is a diagram showing a circuit configuration of the current control device according to Embodiment 1 of the present invention. The current control device 20 shown in the diagram includes a high withstand voltage semiconductor device 40, a comparator circuit 47, a reference voltage generator circuit 48, a sense resistor 49, a gate voltage application circuit 54, and a common electrode 60.

Terminal P4 is connected (grounded) to the common electrode 60 having a constant potential at least in the current control device 20, and Terminal P3 is connected (grounded) to the common electrode 60 through the sense resistor 49 which is a resistor used to detect a current.

The reference voltage generator circuit 48 is a first reference voltage generator circuit which generates a first reference voltage with respect to the voltage of the common electrode 60.

The comparator 47 is connected to Terminal P3 having a first input terminal connected to the emitter/source electrode 61 and having a second input terminal connected to the reference voltage generator circuit 48. The comparator 47 compares (i) the first voltage generated between both the terminals of the sense resistor 49 which is the first resistor element with (ii) the first reference voltage generated by the reference voltage generator circuit 48 when an electron current 46 that is the first current flows into the sense resistor 49. Here, the first current is a current that flows into the emitter/source electrode 61 among the collector/drain current of the high withstand voltage semiconductor device 40.

The gate voltage application circuit 54 controls the collector/drain current according to the result of the comparison made by the comparator circuit 47.

As for a current control method, the high withstand voltage semiconductor device 40 configured as the circuit shown in FIG. 3 applies a positive bias to Terminals P1 and P3 and applies a positive voltage to Terminal P2 so as to cause the electron current 46 to start flowing from Terminal P1 to Terminal P3 (MOSFET operation). An increase of electron current 46 to a certain level (1 A in the example of FIG. 11) triggers a transition to an IGBT operation, causing the hole current 45 that is a second current to start flowing into Terminal P4. The electron current 46 keeps increasing with increases in the collector/drain current flowing into Terminal P1 even after the transition to the IGBT operation is completed. At this time, the voltage generated in the sense resistor 49 increases more significantly with increases in the electron current 46. When the first voltage generated by the electron current 46 subsequently reaches the first reference voltage generated by the reference voltage generator circuit 48, a signal is propagated from the comparator circuit 47 to the gate voltage application circuit 54. This turns off Terminal P2 having a positive bias, which makes the voltage equal to the voltage of the common electrode 60, resulting in cut-offs of the electron current 46 and the hole current 45.

Next, a description is given of an advantageous effect provided by the current control device 20 shown in FIG. 3. In the circuit configured as shown in FIG. 3, since the sense resistor 49 is connected to Terminal P3, and Terminal P4 is connected to the common electrode 60, Terminal P3 has a potential higher than the potential of Terminal P4 during a turned-on state in which a current is flowing. In other words, the emitter/source electrode 61 has a potential higher than the potential of the back gate electrode 62 in the high withstand voltage semiconductor device 40 shown in FIG. 1.

While the high withstand voltage semiconductor device 40 is in a turned-on state, particularly during an IGBT operation, a hole current from the P-type collector region 31 passes through the P-type base region 10 and the P⁺-type base contact region 15 and then flows into the back gate electrode 62. At this time, resistance components of the P-type base region 10 inevitably cause a so-called latch-up. Here, a latch-up is a phenomenon in which an undesirable current flows from the P-type base region 10 to the N⁺-type emitter/source region 14 when the potential of the P-type base region 10 becomes greater than the potential of the N⁺-type emitter/source region 14 by approximately 0.6 V.

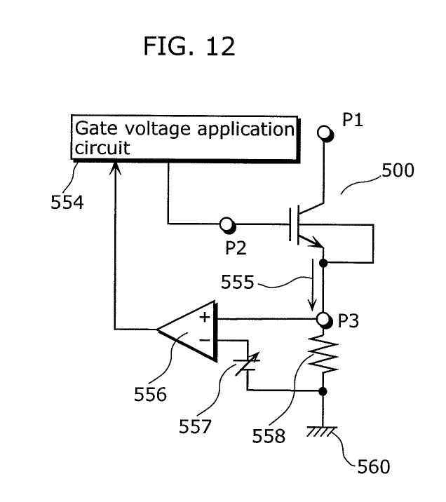

However, the current control device 20 configured as a circuit according to this embodiment of the present invention can increase the potential of the emitter/source electrode 61 exceeding the potential of the back gate electrode 62, and thus the voltage generated by the hole current and the base resistor rarely reaches 0.6 V. Accordingly, the current control device 20 has an advantageous effect of being able to increase the resistance against the so-called latch-up exceeding the resistance of the conventional current control device shown in FIG. 12. The latch-up is a phenomenon in which an undesirable current flows from the P-type base region 10 to the N⁺-type emitter/source region 14.

In addition, a current that flows in the sense resistor 49 is only the electron current 46 that flows in Terminal P3 even when the high withstand voltage semiconductor device 40 is under execution of an IGBT operation. On the other hand, in the case of the conventional current control device shown in FIG. 12, the current 555 that flows into the sense resistor 558 is a sum of the electron current and the hole current. Accordingly, when the same amount of collector/drain current is applied, the current control device 20 can reduce the current that flows in the sense resistor more significantly than in the case of using the conventional current control device. As the result, the current control device 20 has an advantageous feature of being able to reduce losses generated in the sense resistor more significantly than in the case of using the conventional configuration.

The above descriptions in this embodiment have been given assuming that the high withstand voltage semiconductor device 40 is a horizontally-disposed device in which a current flows in the horizontal direction with respect to the semiconductor substrate, but it is also good to use it as a vertically-disposed device in which a current flows in the vertical direction.

In addition, in the current control device 20 shown in FIG. 3, the high withstand voltage semiconductor device 40 may be configured in a chip separately from the other circuits such as the sense resistor 49, the reference voltage generator circuit 48, the comparator circuit 47, and the gate voltage application circuit 54 which are integrated in another chip. Otherwise, the high withstand voltage semiconductor device 40 and the other circuits may be integrally formed within a semiconductor substrate.

### Embodiment 2

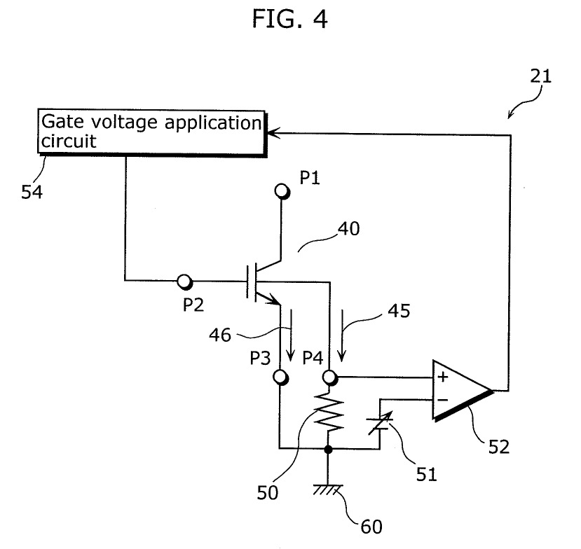

FIG. 4 is a diagram showing a circuit configuration of the current control device according to Embodiment 2 of the present invention. The current control device 21 shown in the diagram includes a high withstand voltage semiconductor device 40, a comparator circuit 52, a reference voltage generator circuit 51, a sense resistor 50, a gate voltage application circuit 54, and a common electrode 60.

Terminal P3 is connected (grounded) to the common electrode 60 having a constant potential at least in the current control device 20, and Terminal P4 is connected (grounded) to the common electrode 60 through the sense resistor 50 which is a resistor used to detect a current.

The reference voltage generator circuit 51 is a second reference voltage generator circuit which generates a second reference voltage with respect to the voltage of the common electrode 60.

The comparator circuit 52 is connected to Terminal P4 having a first input terminal connected to the back gate electrode 62 and having a second input terminal connected to the reference voltage generator circuit 51. The comparator 52 compares (i) the second voltage generated between both the terminals of the sense resistor 50 which is the second resistor element with (ii) the second reference voltage generated by the reference voltage generator circuit 51 when a hole current 45 that is the second current flows into the sense resistor 50. Here, the second current is a current that flows into the back gate electrode 62 among the collector/drain current of the high withstand voltage semiconductor device 40.

The gate voltage application circuit 54 controls the collector/drain current according to the result of the comparison made by the comparator circuit 52.

As for a current control method, the high withstand voltage semiconductor device 40 configured as the circuit shown in FIG. 4 applies a positive bias to Terminals P1 and P3 and applies a positive voltage to Terminal P2 so as to cause the electron current 46 to start flowing from Terminal P1 to Terminal P3 (MOSFET operation). An increase of electron current 46 to a certain level (1 A in the example of FIG. 11) triggers a transition to an IGBT operation, causing the hole current 45 to start flowing into Terminal P4. The hole current 45 keeps increasing with increases in the collector/drain current flowing into Terminal P1 even after the transition to the IGBT operation is completed. At this time, the voltage generated in the sense resistor 50 increases more significantly with increases in the hole current 45. When the second voltage generated by the hole current 45 reaches the second reference voltage generated by the reference voltage generator circuit 51, a signal is propagated from the comparator circuit 52 to the gate voltage application circuit 54. This turns off Terminal P2 having a positive bias, which makes the voltage equal to the voltage of the common electrode 60, resulting in cut-offs of the hole current 45 and electron current 46.

Next, a description is given of an advantageous effect provided by the current control device 21 shown in FIG. 4.

Since the sense resistor 50 is connected to Terminal P4, and Terminal P3 is connected to the common electrode 60 in the circuit configured as shown in FIG. 4, it is possible to detect, using the sense resistor 50, the hole current 45 that starts flowing when the high withstand voltage semiconductor device 40 switches from a MOS operation to an IGBT operation.

As an exemplary case, it is assumed that the second reference voltage generated by the reference voltage generator circuit 51 is variable within a range from 0.02 to 0.3 V inclusive, and that the sense resistor 50 has 0.2Ω. In this case, a switch from a MOS operation to an IGBT operation is detected when the second reference voltage is, for example, 0.03 V. This switch from the MOS operation to the IGBT operation is accurately detected when the high withstand voltage semiconductor device 40 causes a transition to the IGBT operation, causing a hole current 45 to start flowing into Terminal P4, and subsequently causing the voltage generated in the sense resistor 50 to reach 0.03 V, that is, causing the hole current 45 to reach 0.15 A. On the other hand, when the voltage generated in the sense resistor 50 is below 0.03 V, it is possible to detect a switch from the IGBT operation to a next MOS operation.

As described above, according to this embodiment, it is possible to accurately detect a switch from a MOS operation to an IGBT operation although such detection cannot be performed by the conventional current control device shown in FIG. 12.

In addition, a current that flows in the sense resistor 50 is only the hole current 45 that flows in Terminal P4 even when the high withstand voltage semiconductor device 40 is under execution of an IGBT operation. On the other hand, in the case of the conventional current control device shown in FIG. 12, the current 555 that flows into the sense resistor 558 is a sum of the electron current and the hole current. Accordingly, when the same amount of collector/drain current is applied, the current control device 21 according to this embodiment can reduce the current that flows in the sense resistor more significantly than in the case of using the conventional current control device. As the result, the current control device 20 has an advantageous feature of being able to reduce losses generated in the sense resistor more significantly than in the case of using the conventional configuration.

### Embodiment 3

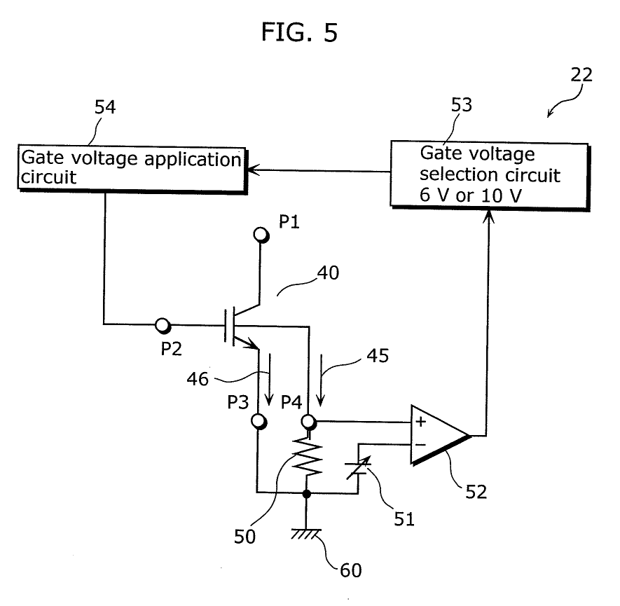

FIG. 5 is a diagram showing a circuit configuration of the current control device according to Embodiment 3 of the present invention. The current control device 22 shown in the diagram includes a high withstand voltage semiconductor device 40, a comparator circuit 52, a reference voltage generator circuit 51, a sense resistor 50, a gate voltage application circuit 54, a common electrode 60, and a gate voltage selection circuit 53.

The current control device 22 according to this embodiment is structurally different from the current control device 21 according to this embodiment in having the gate voltage selection circuit 53 which receives a signal from the comparator circuit 52. Only differences are described below without repeating the same descriptions given of the current control device 21 according to Embodiment 2.

The gate voltage selection circuit 53 receives a signal from the comparator circuit 52, and increases the gate voltage value, of the high withstand voltage semiconductor device 40, which is applied to Terminal P2 when the second voltage generated in the sense resistor 50 becomes equal to or above the second reference voltage generated by the reference voltage generator circuit 51. On the other hand, when the second voltage becomes equal to or below the second reference voltage, the gate voltage selection circuit 53 capable of decreasing the gate voltage value, of the high withstand voltage semiconductor device 40, which is applied to Terminal P2.

For example, upon detection of a switch from an MOS operation to an IGBT operation of the high withstand voltage semiconductor device 40, the gate voltage selection circuit 53 can switch the gate voltages to be applied to Terminal P2 between 6 V for the MOS operation and 12 V for the IGBT operation.

Next, a detailed description is given of a switch of the gate voltages between the MOS operation and the IGBT operation.

FIG. 11 is a graph showing correlations between collector/drain voltages and collector/drain currents of the high pressure resistant semiconductor device. As clear from FIG. 11, in the MOS operation region in which Vch is smaller than 2 V, the current drive capability is maintained as long as the voltage of Terminal P2, that is, the gate voltage Vg is not less than 6 V.

Therefore, the use of 6 V as Vg in the MOS operation region reduces drive losses more significantly than in the case of using 12 V as Vg. In contrast, in the IGBT operation region in which Vch is greater than 2 V, the current drive capability is greatly different depending on whether Vg is 6 V or 12 V. The use of 12 V as Vg in this region reduces losses caused by a turned-on resistor more significantly than in the case of using 6 V as Vg.

As described above, in order to reduce losses to an optimum level, it is necessary to accurately detect a switch between a MOS operation and an IGBT operation, reduce drive losses using 6 V as the gate voltage during the MOS operation and reduces losses caused by the turned-on transistor using 12 V as the gate voltage during the IGBT operation.

Here, a detailed description is given below of drive losses during the MOS operation.

A gate drive loss P of the high withstand voltage semiconductor device 40 is expressed by Expression 1, and increases in relation to the squares of the gate voltage Vg.

P=½×C×Vg²×2×fosc (Expression 1)

Thus, assuming that a gate capacitance C of the high withstand voltage semiconductor device 40 is 1000 pF, and a drive frequency fosc is 100 kHz, the gate drive loss P is 14 mW when Vg is 12 V according to Expression 1. On the other hand, when the gate voltage is 6 V, the gate drive loss P is 4 mW with a loss reduction of 10 mW.

As described above, the current control device 22 in the present invention can accurately detect a switch between an MOS operation and an IGBT operation, reduce the drive losses using 6 V as the gate voltage during the MOS operation, and reduce losses caused by the turned-on resistor using 12 V as the gate voltage during the IGBT operation. Therefore, the current control device 22 can reduce losses more significantly than the current control device 21 described in Embodiment 2 does.

### Embodiment 4

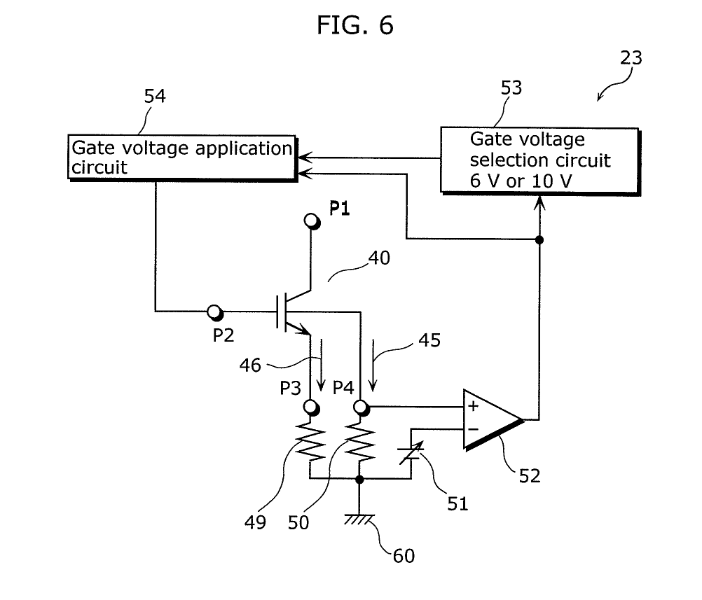

FIG. 6 is a diagram showing a circuit configuration of the current control device according to Embodiment 4 of the present invention. The current control device 23 shown in the diagram includes a high withstand voltage semiconductor device 40, a comparator circuit 52, a reference voltage generator circuit 51, sense resistors 49 and 50, a gate voltage application circuit 54, a common electrode 60, and a gate voltage selection circuit 53.

The current control device 23 according to this embodiment is structurally different from the current control device 22 according to Embodiment 3 in that Terminal P3 is connected (grounded) to the common electrode through the sense resistor 49 which is a resistor used to prevent a latch-up. Only differences are described below without repeating the same descriptions given of the current control device 22 according to Embodiment 3.

The sense resistor 49 for preventing a latch-up increases the potential of Terminal P3 with respect to the potential of the common electrode 60 during a turned-on state in which a current is flowing. This increases the potential of Terminal P3 during the turned-on state to a certain level exceeding the potential of Terminal P3 of the current control device 22 according to Embodiment 3 shown in FIG. 5. In other words, in this embodiment, the emitter/source electrode 61, in the high withstand voltage semiconductor device 40 shown in FIG. 1, has a potential higher than the corresponding potential in Embodiment 3.

As the result, it is possible to increase a resistance against a so-called latch-up more significantly than in the case of using the current control device 22 shown in FIG. 5. The latch-up is a phenomenon in which an undesirable current flows from a P-type base region 10 to an N⁺-type emitter/source region 14.

### Embodiment 5

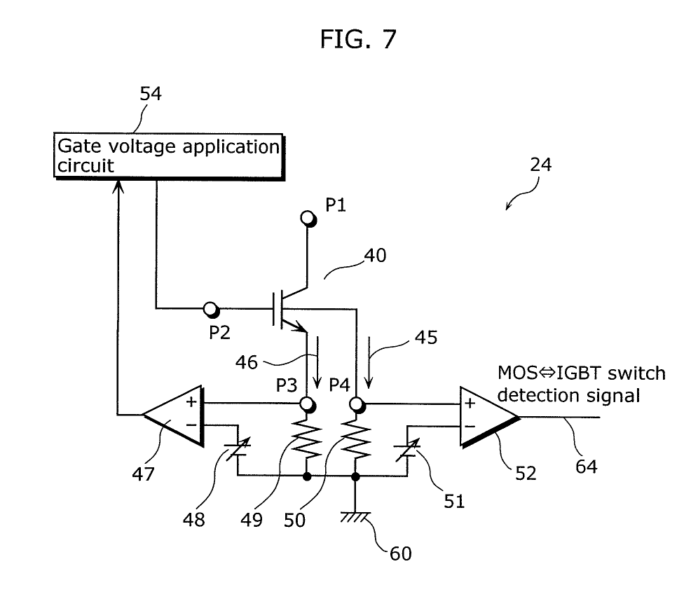

FIG. 7 is a diagram showing a circuit configuration of the current control device according to Embodiment 5 of the present invention. The current control device 24 shown in the diagram includes a high withstand voltage semiconductor device 40, comparator circuits 47 and 52, reference voltage generator circuits 48 and 51, sense resistors 49 and 50, a gate voltage application circuit 54, and a common electrode 60.

Terminal P3 is connected (grounded) to the common electrode 60 through the sense resistor 49 which is a resistor used to detect a current, and Terminal P4 is connected (grounded) to the common electrode 60 through the sense resistor 50 which is also a resistor used to detect a current.

The reference voltage generator circuit 48 is a third reference voltage generator circuit which generates a third reference voltage with respect to the voltage of the common electrode 60.

The reference voltage generator circuit 51 is a second reference voltage generator circuit which generates a second reference voltage with respect to the voltage of the common electrode 60.

The comparator 47 is a third comparator having a first input terminal connected to Terminal P3 which is connected to the emitter/source electrode 61 and having a second input terminal connected to the reference voltage generator circuit 48. The comparator 47 compares (i) the third voltage generated between both the terminals of the sense resistor 49 which is the third resistor element with (ii) the third reference voltage generated by the reference voltage generator circuit 48 when an electron current 46 that is the first voltage flows into the sense resistor 49. Here, the first current is a current that flows into the emitter/source electrode 61 among the collector/drain current of the high withstand voltage semiconductor device 40.

The comparator circuit 52 is a second comparator having a first input terminal connected to Terminal P4 which is connected to the back gate electrode 62 and having a second input terminal connected to the reference voltage generator circuit 51. The comparator 52 compares (i) the second voltage generated between both the terminals of the sense resistor 50 which is the second resistor element with (ii) the second reference voltage generated by the reference voltage generator circuit 51 when a hole current 45 that is the second voltage flows into the sense resistor 50. Here, the second current is a current that flows into the back gate electrode 62 among the collector/drain current of the high withstand voltage semiconductor device 40.

The gate voltage application circuit 54 controls the collector/drain current according to the result of the comparison made by the comparator circuit 47.

As for a current control method, the high withstand voltage semiconductor device 40 configured as the circuit shown in FIG. 7 applies a positive bias to Terminals P1 and P3 and applies a positive voltage to Terminal P2 so as to cause the electron current 46 to start flowing from Terminal P1 to Terminal P3 (MOSFET operation). An increase of electron current 46 to a certain level (1 A in the example of FIG. 11) triggers a transition to an IGBT operation, causing the hole current 45 to start flowing into Terminal P4. The electron current 46 keeps increasing with increases in the collector/drain current flowing into Terminal P1 even after the transition to the IGBT operation is completed. At this time, the voltage generated in the sense resistor 49 increases more significantly with increases in the electron current 46. When the second voltage generated by the hole current 45 reaches the third reference voltage generated by the reference voltage generator circuit 48, a signal is propagated from the comparator circuit 47 to the gate voltage application circuit 54. This turns off Terminal P2 having a positive bias, which makes the voltage equal to the voltage of the common electrode 60, resulting in cut-offs of the electron current 46 and the hole current 45.

Further, the circuit configured as shown in FIG. 7 can detect, using the sense resistor 50 connected to Terminal P4, the hole current 45 that starts flowing when the high withstand voltage semiconductor device 40 switches from a MOS operation to an IGBT operation since the sense resistor 50 is connected to Terminal P4.

As a concrete example, it is assumed that the second reference voltage generated by the reference voltage generator circuit 51 is set to be 0.03 V, and that the sense resistor 50 has 0.2Ω.

When the high withstand voltage semiconductor device 40 causes a transition to the IGBT operation, the hole current 45 starts flowing into Terminal P4, and then the voltage generated in the sense resistor 50 reaches 0.03 V, that is, the flowing hole current 45 reaches 0.15 A. At this time, a detection signal 64 is outputted from the comparator circuit 52. The use of this detection signal 64 makes it possible to accurately detect a switch from a MOS operation to an IGBT operation. On the other hand, when the voltage generated in the sense resistor 50 is below 0.03 V, it is possible to detect a switch from the IGBT operation to a next MOS operation.

As described above, unlike the current control device 21 according to Embodiment 2 shown in FIG. 4, the current control device 24 according to Embodiment 5 shown in FIG. 7 can detect, using the sense resistor 49, the electron current 46, and thus has an advantageous feature of being able to control a collector/drain current in the MOS operation region (that covers a range up to 1 A in FIG. 11). In other words, the use of this configuration enables control of a collector/drain current even in the MOS operation region although the high withstand voltage semiconductor device 40 in Embodiment 2 cannot detect a collector/drain current during an MOS operation because the sense resistor 50 is connected only to Terminal P4.

In addition, the sense resistor 49 connected to Terminal P3 increases the potential of Terminal P3 with respect to the potential of the common electrode 60 during a turned-on state in which a current is flowing. This increases the potential of Terminal P3 during the turned-on state to the level exceeding the potential of Terminal P3 of the current control device 21 according to Embodiment 2. In other words, in this embodiment, the emitter/source electrode 61 in the high withstand voltage semiconductor device 40 shown in FIG. 1 has a potential higher than the potential of the corresponding electrode in Embodiment 2.

As the result, it is possible to increase a resistance against a so-called latch-up more significantly than in the case of using the current control device 21 according to Embodiment 2. The latch-up is a phenomenon in which an undesirable current flows from a P-type base region 10 to an N⁺-type emitter/source region 14.

### Embodiment 6

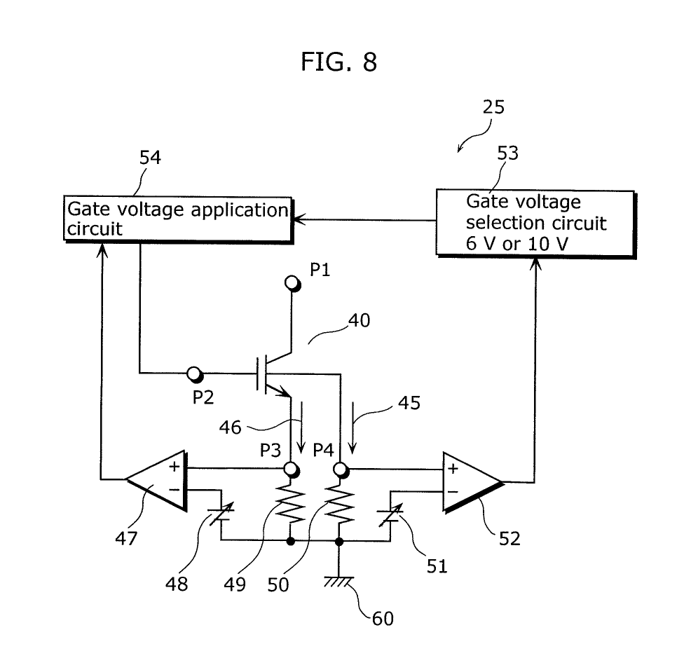

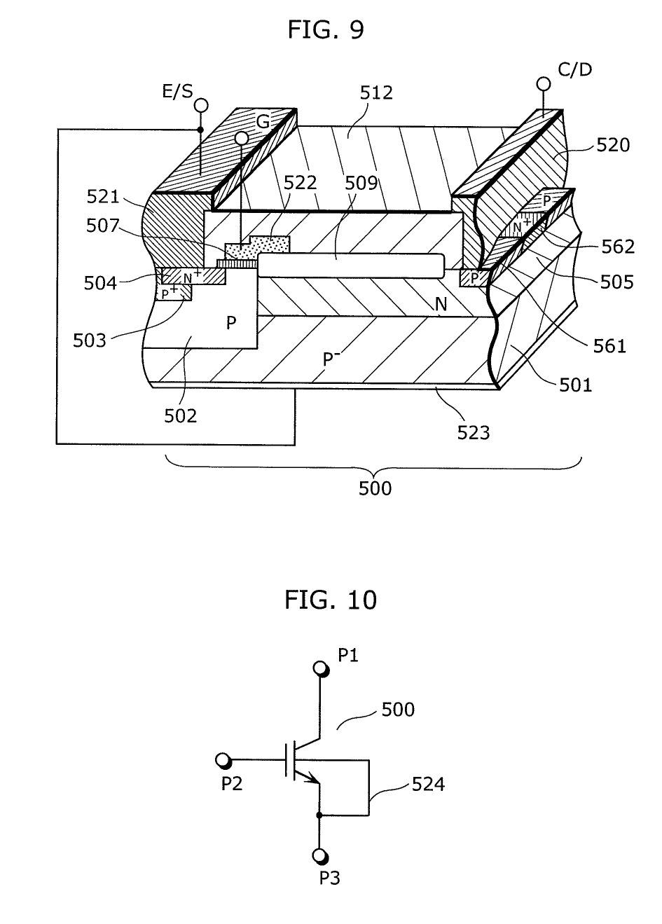

FIG. 8 is a diagram showing a circuit configuration of the current control device according to Embodiment 6 of the present invention. The current control device 25 shown in the diagram includes a high withstand voltage semiconductor device 40, comparator circuits 47 and 52, reference voltage generator circuits 48 and 51, sense resistors 49 and 50, a gate voltage application circuit 54, a common electrode 60, and a gate voltage selection circuit 53.

The current control device 25 according to this embodiment is structurally different from the current control device 24 according to Embodiment 5 in having the gate voltage selection circuit 53 which receives a signal from the comparator circuit 52. Only differences are described below without repeating the same descriptions given of the current control device 24 according to Embodiment 5.

The gate voltage selection circuit 53 receives a signal from the comparator circuit 52, and increases the gate voltage value, of the high withstand voltage semiconductor device 40, which is applied to Terminal P2 when the second voltage generated between both the terminals of the sense resistor 50 is equal to or above the second reference voltage generated by the reference voltage generator circuit 51. On the other hand, when the second voltage is below the second reference voltage, the gate voltage selection circuit 53 is capable of decreasing the gate voltage value, of the high withstand voltage semiconductor device 40, which is applied to Terminal P2.

As described above, the current control device in the present invention can accurately detect a switch between an MOS operation and an IGBT operation, reduce the drive losses using 6 V as the gate voltage during the MOS operation, and reduce losses caused by the turned-on resistor using 12 V as the gate voltage during the IGBT operation. Therefore, the current control device 52 can reduce losses more significantly than the current control device 24 described in Embodiment 2 does.

According to the high pressure resistant semiconductor device and the current control device using the same in the present invention, it is possible to perform an accurate detection of a switch between an MOS operation and an IGBT operation, thereby enabling a low-loss drive.

It is to be noted that the high withstand voltage semiconductor devices and the current control devices using the same according to the present invention are not limited to those in the above-described embodiments. Those skilled in the art will readily appreciate that many modifications and variations of the exemplary embodiments are possible by combining arbitrary structural elements in Embodiments 1 to 6 without materially departing from the novel teachings and advantages of this invention, and that the high withstand voltage semiconductor devices and the current control devices can be installed in various devices. Accordingly, all such modifications and implementations are intended to be included within the scope of the present invention.

### INDUSTRIAL APPLICABILITY

A current control device using a high withstand voltage semiconductor device according to the present invention is useful particularly as a component used for a switching power source device which achieves a low power consumption during standby.

What is claimed is:

1. A high withstand voltage semiconductor device comprising:
a second conductive-type resurf region formed on a surface part of a first conductive-type semiconductor substrate;
a first conductive-type base region formed adjacent to said resurf region in said semiconductor substrate;
a second conductive-type emitter/source region formed in said base region and apart from said resurf region;
a gate insulation film formed on said semiconductor substrate to cover said base region at a part between said emitter/source region and said resurf region;
a second conductive-type drain region formed in said resurf region and apart from said base region;
a first conductive-type collector region formed in said resurf region and apart from said base region;
a gate electrode formed on said gate insulation film;
a collector/drain electrode formed on said semiconductor substrate and electrically connected to both said collector region and said drain region;
a back gate electrode formed on said semiconductor substrate and electrically connected to said base region; and
an emitter/source electrode formed on said semiconductor substrate and electrically connected to said emitter/source region,
wherein said collector region and said drain region are each configured with separate parts, and arranged such that the respective parts of said collector region and the respective parts of said drain region are alternately in contact with each other in a direction perpendicular to a direction from said collector region to said emitter/source region.

2. A current control device comprising:
the high withstand voltage semiconductor device according to claim 1; and
a current control unit configured to control a collector/drain current according to a result of detection of a value of at least one of (i) a first current flowing into said emitter/source electrode in the collector/drain current of said high withstand voltage semiconductor device and (ii) a second current flowing into said back gate electrode in the collector/drain current.

3. The current control device according to claim 2,
wherein said back gate electrode is connected to a common electrode having a constant potential at least in said current control unit, and
said current control unit includes:
a first resistor element which is inserted between said emitter/source electrode and said common electrode, and is configured to detect the first current flowing into said common electrode;
a first reference voltage generator circuit which generates a first reference voltage that is a potential with respect to the potential of said common electrode;
a first comparator circuit which has a first input terminal connected to said emitter/source electrode and has a second input terminal connected to said first reference voltage generator circuit, and compares (i) a first voltage generated between both terminals of said first resistor element with (ii) the first reference voltage; and
a current control circuit which controls the collector/drain current according to a result of the comparison made by said first comparator circuit.

4. The current control device according to claim 2,
wherein said emitter/source electrode is connected to a common electrode having a constant potential at least in said current control unit, and
said current control unit includes:
a second resistor element which is inserted between said back gate electrode and said common electrode, and is configured to detect the second current flowing into said common electrode;
a second reference voltage generator circuit which generates a second reference voltage that is a potential with respect to the potential of said common electrode;
a second comparator circuit which has a first input terminal connected to said back gate electrode and a second input terminal connected to said second reference voltage generator circuit, and compares (i) a second voltage generated between said both terminals of said second resistor element with (ii) the second reference voltage; and
a current control circuit which controls the collector/drain current according to a result of the comparison made by said second comparator circuit.

5. The current control device according to claim 4,
wherein said current control unit further includes
a resistor element for preventing a latch-up which is inserted between said emitter/source electrode and said common electrode, and is configured to prevent a latch-up.

6. The current control device according to claim 4,
wherein said current control unit further includes:
a third resistor element which is inserted between said emitter/source electrode and said common electrode, and is configured to detect the first current flowing into said common electrode;
a third reference voltage generator circuit which generates a third reference voltage that is a potential with respect to the potential of said common electrode; and
a third comparator circuit which has a first input terminal connected to said emitter/source electrode and a second input terminal connected to said third reference voltage generator circuit, and compares (i) a third voltage generated between said both terminals of said third resistor element with (ii) the third reference voltage,
wherein said current control circuit controls said collector/drain current according to a result of the comparison made by said first and third comparator circuits.

7. The current control device according to claim 4,
wherein said current control circuit includes
a gate voltage selection circuit which:
increases a gate voltage value of said high withstand voltage semiconductor device according to a signal received from said second comparator circuit when the second voltage reaches or exceeds the second reference voltage; and
decreases a gate voltage value of said high withstand voltage semiconductor device according to a signal received from said second comparator circuit when the second voltage reaches or falls below the second reference voltage.
